(19) United States
(12) Patent Application Publication
(10) Pub. No.: US 2011/0174775 A1
(43) Pub. Date: Jul. 21, 2011

(54) SURFACE PROCESSING APPARATUS

(75) Inventors: Takashi Umeoka, Ibaraki (JP); Hirofumi Yagisawa, Ibaraki (JP); Satoshi Mayumi, Kyoto (JP); Takashi Satoh, Kyoto (JP); Shunsuke Kunugi, Kyoto (JP)

(73) Assignee: SEKISUI CHEMICAL CO., LTD., Osaka-shi, Osaka (JP)

(21) Appl. No.: 13/120,196

(22) PCT Filed: Sep. 16, 2009
(86) PCT No.: PCT/JP2009/004632

§ 371 Date: Mar. 22, 2011

(30) Foreign Application Priority Data
Sep. 30, 2008 (JP) 2008-252332

(51) Int. Cl. C23F 1/00; C23C 16/455; C23C 16/458; C23C 16/52; C23F 1/08

(52) U.S. Cl. 216/58; 118/729; 118/719; 427/248.1; 156/345.29

(57) ABSTRACT

To prevent a processing gas from leaking from a processing tank for processing a surface of a substrate and to stabilize flow of the processing gas in a processing space.

A substrate 9 is conveyed into the inside of a processing tank 10 through an entrance port 13 by a conveyor 20 and positioned in a processing space 19. A processing gas is supplied to the processing space 19 by a supply system 30, and the substrate 9 is surface processed. Subsequently, the substrate 9 is conveyed out through an exit port 14. Gas inside of the processing tank 10 is exhausted by an exhaust system 40. The exhausting of gas causes gas outside of the processing tank 10 to inflow into the inside of the processing tank 10 through the openings 13, 14 such that an average flow velocity of the inflow gas is at least 0.1 m/sec yet smaller than a velocity that would allow the inflow gas to reach the processing space 19.

### TECHNICAL FIELD

The present invention relates to an apparatus for processing a surface of a substrate by bringing a processing gas into contact with the surface of the substrate, and particularly relates to a surface processing apparatus suitable for processing using a processing gas having toxic properties or corrosive properties.

### BACKGROUND ART

Apparatus that blow a processing gas onto a substrate such as a glass substrate or a semiconductor wafer and perform surface processing such as etching, cleaning, surface modification and deposition are known in the art. The processing gas used in this kind of surface processing often contains compounds that are not preferable in terms of safety or environment if the gas leaks to the outside. A common way to cope with this problem is to enclose a processing space within a processing tank (chamber) to prevent the processing gas from leaking to the outside.

In the surface processing apparatus of Patent Documents 1 and 2, a processing tank (chamber) has an entrance for leading a substrate into the tank and an exit for leading the substrate out of the tank. The entrance and the exit are slit-shaped. Buffer rooms are provided in opposite ends of the processing tank to moderate an outflow of a plasma-generating gas and an inflow of external air into the processing tank. Gas inside the processing tank is exhausted through an exhaust opening.

A surface processing apparatus in Patent Document 3 includes an inner tank enclosing a discharge plasma generator and an outer tank enclosing the inner tank. An inner pressure of a space between the outer tank and the inner tank is lower than an inner pressure of the inner tank and lower than the external air pressure. As a result, the processing gas flows out of the inner tank into the space between the outer tank and the inner tank and the external air flows into the outer tank.

### PRIOR ART DOCUMENTS

### Patent Documents

Patent Document 1: Japan Patent Publication No. 4058857 (FIG. 9)
Patent Document 2: Japan Patent Publication No. 3994596 (FIG. 7)
Patent Document 3: Japan Patent Application Publication No. 2003-142298

### SUMMARY OF THE INVENTION

### Problem to be Solved by the Invention

A processing tank needs an opening for a substrate to be conveyed in and out therethrough. However, there is a possibility that a processing gas inside the tank will leak through the opening. One way to prevent such leaking may be to connect an exhaust unit to the tank for exhausting gas from the tank. This can direct a gas flow through the opening from outside of the tank to inside of the tank. However, if the exhaust flow rate is excessively high, there is a possibility that external air will flow swiftly into the tank through the opening and disturb the flow of processing gas in the processing space. Moreover, it could increase the burden for detoxifying and recycling the exhaust gas.

### Solution to the Problem

To solve the problems mentioned above, the present invention provides an apparatus that processes a surface of a substrate by bringing a processing gas into contact with the surface of the substrate, the apparatus comprising:

a processing tank having an entrance port and an exit port, and a processing space disposed inside of the processing tank at a location spaced apart from the entrance port and the exit port for performing the surface processing;

a conveyor that conveys the substrate into the inside of the processing tank through the entrance port, positions the substrate in the processing space and subsequently conveys the substrate through the exit port;

a supply system that supplies the processing gas to the processing space; and

an exhaust system that exhausts gas from the inside of the processing tank

wherein the exhausting of gas by the exhaust system causes a gas outside the processing tank to inflow into the inside of the processing tank through the port such that an average flow velocity of the inflow gas is at least 0.1 m/sec yet smaller than a velocity that would allow the inflow gas to reach the processing space.

By setting the average flow velocity of the inflow to be at least 0.1 m/sec, the processing gas can be prevented from leaking to the outside of the processing tank through the entrance port or the exit port. Setting an upper limit of the average flow velocity of the inflow causes the inflow gas to be sufficiently attenuated in a space between the entrance port or the exit port and the processing space, thereby preventing the inflow gas from reaching the processing space. Accordingly, the flow of processing gas in the processing space can be protected from being disturbed by the inflow gas, allowing the flow of the processing gas to be stabilized such that the surface processing can be performed in a stable manner. Moreover, this allows constant ventilation of the inside of the processing tank such that the concentration of the processing gas inside the processing tank can be maintained constant for more stable surface processing. Furthermore, since the exhaust flow rate in the exhaust system will be relatively small, the burden of exhaust gas processing can be minimized in a case where detoxification and recovery is performed.

Preferably, the average flow velocity of the inflow gas is a value determined when the substrate is not located inside of or near the entrance port or the exit port.

Preferably, the entrance port and the exit port are constantly open. This enables a plurality of substrates to be successively conveyed into the processing tank, processed and then conveyed out in a continuous manner.

Preferably, the average flow velocity of the inflow gas is at least 0.3 m/sec.

By this arrangement, the processing gas can be more securely prevented from leaking through the entrance port or the exit port.

Preferably, the average flow velocity of the inflow gas is not greater than 2 m/sec, more preferably not greater than 1 m/sec, and further more preferably, not greater than 0.7 m/sec.

By this arrangement, the flow of the processing gas in the processing space can be more securely protected from being disturbed. This can ensure stable flow of the processing gas, thereby enabling the surface processing to be performed in a reliable and stable manner.

Still more preferably, the average flow velocity is 0.3 m/sec to 0.7 m/sec. By this arrangement, the processing gas can be more securely prevented from leaking through the entrance port or the exit port and the flow of the processing gas in the processing space can be more securely protected from being disturbed.

Preferably, the inside of the processing tank is partitioned in a conveying direction of the conveyor into a plurality of chambers by one or more partitioning walls, wherein a communication opening for passing the substrate therethrough is provided in each of the partitioning walls, wherein the processing space is provided in an inside of one chamber (referred to as a “first chamber” hereinafter) of the plurality of chambers and the supply system and the exhaust system are directly connected to the first chamber. This arrangement can more securely prevent the processing gas from leaking.

Preferably, the exhausting of gas by the exhaust system causes inflow gas to flow through the communication opening toward the processing space such that an average flow velocity at which the inflow gas that has passed through the communication opening, flows into the first chamber on a downstream side of the communication opening is at least 0.1 m/sec, and more preferably, at least 0.3 m/sec.

By this arrangement, the processing gas can be more securely prevented from leaking.

Still more preferably, the average flow velocity of the inflow gas flowing into the first chamber on the downstream side of the communication opening is from 0.3 m/sec to 0.7 m/sec. By this arrangement, the processing gas can be more securely prevented from leaking and the flow of the processing gas can be more securely protected from being disturbed.

Preferably, the processing space of the first chamber is spaced apart from the communication opening (referred to as “first communication opening” hereinafter) of the partitioning wall facing the first chamber. Preferably, the exhausting of the gas by the exhaust system causes inflow gas to flow through the first communication opening toward the processing space such that an average flow velocity at which the gas that has passed through the first communication opening flows into the first chamber is at least 0.1 m/sec yet smaller than a velocity that would allow the inflow gas in the first chamber to reach the processing space.

This can more securely prevent the processing gas from leaking and can ensure flow stability of the processing gas in the processing space, thus enabling the surface processing to be performed in a reliable and stable manner.

Preferably, the plurality of chambers include three or more chambers and the first chamber is a chamber other than chambers disposed in the opposite ends of the conveying direction.

More preferably, the average flow velocity of the inflow gas into the first chamber is at least 0.3 m/sec.

By this arrangement, the processing gas can be more securely prevented from leaking.

Still more preferably, the average flow velocity of the inflow gas into the first chamber is 0.3 m/sec to 0.7 m/sec. By this arrangement, the processing gas can be more securely prevented from leaking and the flow of the processing gas can be more securely protected from being disturbed.

Preferably, the exhaust system includes a plurality of exhaust openings arranged in the processing tank in a dispersed manner and regulators that are provided for the exhaust openings on a one-to-one basis to regulate an exhaust flow rate through the corresponding exhaust opening.

This enables gas flow to be controlled over a wide area inside the processing tank, which can prevent the flow of the processing gas from being unevenly distributed in certain directions. Thus, homogeneity of the processing can be secured.

Preferably, the surface processing apparatus further includes a recycle system that collects reactive components of the processing gas from the gas exhausted by the exhaust system and provides the reactive components to the supply system.

By this arrangement, a quantity of the reactive components required for the processing gas can be reduced, resulting in a reduction in running costs. Additionally, the amount of reactive components released to the atmosphere can also be reduced. Therefore, impact on the environment can be minimized when, for example, the reactive components are fluorine compounds or the like that have high global warming potential. Furthermore, since the exhaust flow rate in the exhaust system is relatively small, and consequently the flow rate of ambient gas taken into the processing tank from the outside is relatively small, burden on the recycle system can also be minimized.

Preferably, the surface processing apparatus further includes a post-processor disposed downstream with respect to the processing tank in a conveying direction of the conveyor that performs a post-processing step; a post-processing waiting tank disposed between the processing tank and the post-processor; and a second exhaust system that exhausts gas from inside of the post-processing waiting tank. Preferably, the conveyor conveys the substrate conveyed out of the processing tank through the exit port to the post-processor via the post-processing waiting tank.

There may be cases in which processing gas components or used processing gas components are attached or adsorbed to the substrate that has gone through the surface processing. By conveying the substrate through the post-processing waiting tank after the substrate leaves the processing tank and before the substrate enters the post-processor, even if the attached or adsorbed components volatilize from the substrate, volatilized gas can be confined in the post-processing waiting tank and can be exhausted by the second exhaust system. This can prevent the volatilized gas from leaking to the outside.

Preferably, a second entrance port is provided in a wall of the post-processing waiting tank on the processing tank side and a second exit port is provided in a wall of the post-processing waiting tank on the post-processor side. Preferably, the exit port of the processing tank and the second entrance port of the post-processing waiting tank are spaced along the conveying direction. It is further preferable that a spaced distance between the exit port of the processing tank and the second entrance port of the post-processing waiting tank is 20 to 300 mm.

By setting the spaced distance between the exit port of the processing tank and the second entrance port of the post-processing waiting tank to be at least 20 mm, pressure inside the processing tank and pressure inside the post-processing waiting tank can be prevented from influencing each other. This can prevent the gas inside the processing tank from leaking through the exit port of the processing tank and from being sucked into the post-processing waiting tank, for example. Moreover, this enables the regulation of the respective exhaust flow rates from the processing tank and the post-processing waiting tank to be performed easily. By setting the spaced distance between the exit port of the processing tank and the second entrance port of the post-processing waiting tank to be no more than 300 mm, transfer time from when the substrate leaves the exit port of the processing tank to when the substrate enters the second entrance port of the post-processing waiting tank can be shortened. This can reduce the amount of volatilization of the processing gas components or used processing gas components attached or adsorbed to a surface of the substrate during the transfer time.

The processing tank and the post-processing waiting tank may be attached to each other. The exit port of the processing tank and the second entrance port of the post-processing waiting tank may directly communicate with each other.

Preferably, the surface processing apparatus further includes an outer tank enclosing the processing tank, and a pressure reducer that reduces a pressure of a space between the outer tank and the processing tank to below an atmospheric pressure.

By this arrangement, even if the processing gas leaks from the processing tank, the gas can be confined in an inter-tank space between the outer tank and the processing tank, and the gas can be securely prevented from further leaking to an outside of the outer tank.

Preferably, the surface processing apparatus further includes an outer tank enclosing the processing tank as well as the post-processing waiting tank and a pressure reducer that reduces a pressure of a space between the outer tank and the processing tank and between the outer tank and the post-processing waiting tank to below an atmospheric pressure.

By this arrangement, even if the processing gas leaks from the processing tank, the leaked processing gas can be confined in the inter-tank space between the outer tank and the processing tank and between the outer tank and the post-processing waiting tank, thereby securely preventing the processing gas from further leaking to the outside of the outer tank. Furthermore, even if a volatilized gas is generated from the surface of the substrate between the processing tank and the post-processing waiting tank, or even if a gas volatilized in the post-processing waiting tank leaks from the post-processing waiting tank, the volatilized gas can be confined in the inter-tank space between the outer tank and the processing tank and between the outer tank and the post-processing waiting tank. This can securely prevent the volatilized gas from further leaking to the outside of the outer tank.

### Advantageous Effects of Invention

According to the present invention, processing gas can be prevented from leaking to the outside of a processing tank. Moreover, the flow of processing gas in the processing space can be stabilized, thereby enabling surface processing to be performed in a stable manner. Furthermore, the burden of exhaust gas treatment such as detoxification and recycling of gas exhausted from the exhaust system can be reduced.

### BRIEF DESCRIPTION OF DRAWINGS

FIG. 1 is an explanatory diagram showing a schematic configuration of a first embodiment of the present invention.

FIG. 2 is an explanatory diagram showing a schematic configuration of a second embodiment of the present invention.

FIG. 3 is an explanatory diagram showing a schematic configuration of a third embodiment of the present invention.

FIG. 4 is an explanatory diagram showing a schematic configuration of a fourth embodiment of the present invention.

FIG. 5 is an explanatory diagram showing a schematic configuration of a fifth embodiment of the present invention.

FIG. 6 is an explanatory diagram showing a schematic configuration of a sixth embodiment of the present invention.

### DESCRIPTION OF THE EMBODIMENTS

Embodiments of the present invention will be described hereinafter.

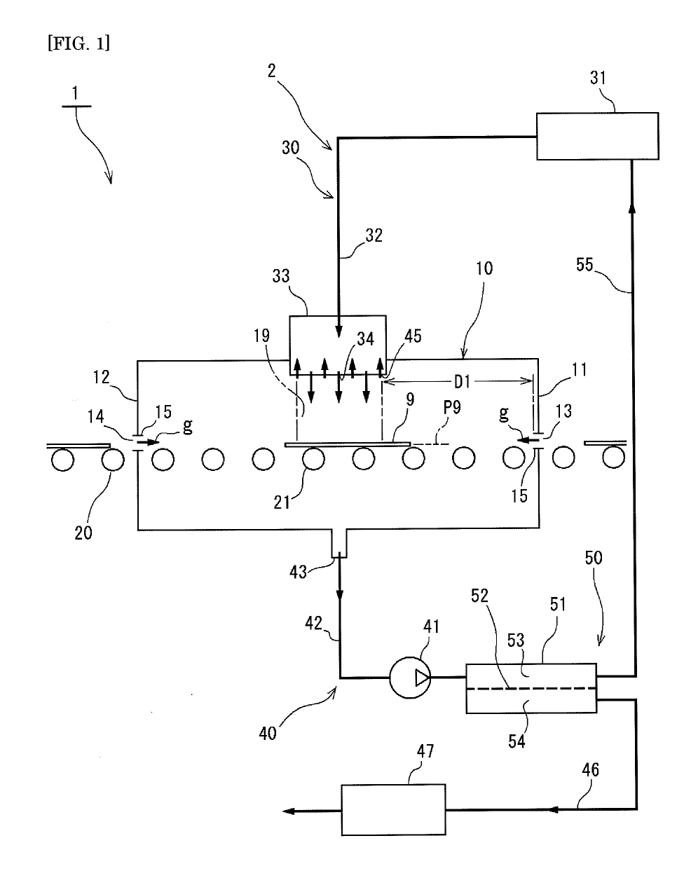

FIG. 1 shows a first embodiment of the present invention. In this embodiment, a substrate 9 is a glass substrate for a flat panel display. However, application of the present invention is not so limited. For example, the present invention may be applied to various kinds of substrates, including but not limited to a semiconductor wafer and a resin film having a continuous sheet configuration. The surface processing performed in this embodiment is the etching of silicon (not shown) coated on a surface of the glass substrate 9. However, application of the present invention is not so limited. For example, the present invention may be applied to etching of oxide silicon or silicon nitride. Furthermore, the application of the present invention is not limited to etching but may also include various kinds of surface processing such as deposition, cleaning, hydrophobization and hydrophilization. The present invention is particularly suitable for processing (etching, deposition, etc.) in which a slight disturbance to the processing gas in the processing space may result in unevenness in the processing.

A length (dimension in a left-right direction in FIG. 1) of the substrate 9 which is a glass substrate for a flat panel display is 1500 mm, for example, and a width (dimension in a direction orthogonal to the plane of FIG. 1) of the substrate 9 is 1100 mm, for example, and a thickness of the substrate 9 is 0.7 mm, for example.

As shown in FIG. 1, a surface processing apparatus 1 includes a processing tank 10, a conveyor 20 and a gas line 2.

The conveyor 20 is a roller conveyor. A multitude (plurality) of rollers 21 of the roller conveyor are disposed spaced from each other in the left-right direction with axes thereof oriented in the direction orthogonal to the plane of FIG. 1. The substrate 9 is placed on the roller 21 and conveyed from right to left (conveying direction) in the drawing. An imaginary horizontal plane at a height in a vicinity of an upper end portion of the roller 21 is a carrying plane P9.

The conveyor 20 is not limited to a roller conveyor, but may include, for example, a mobile stage, a floating stage, a robot arm, etc.

The processing tank 10 (processing chamber) is formed as a container having sufficient dimensions to accommodate the substrate 9 in an inside thereof. A portion of the roller conveyor 20 is located inside the processing tank 10. A processing space 19 is formed in a generally central portion of the inside of the processing tank 10. In other words, the processing tank 10 encloses the processing space 19. The processing space 19 is defined between a supply nozzle 33 to be described later and the conveying plane P9. More specifically, the processing space 19 is, as shown by two vertical chain double-dashed lines in FIG. 1, defined between the supply nozzle 33 bottom surface portion and the projected portion. The projected portion is a projection of the nozzle 33 bottom surface portion vertically projected onto the conveying plane P9. The supply nozzle 33 bottom surface portion is a portion extending from a nozzle discharge opening 34 and a local exhaust opening 45 that are, of the discharge openings 34 and the local exhaust openings 45 in a bottom surface of the supply nozzle 33, located outermost in the left-right direction. In the drawings, a thickness of the processing space 19 (distance between the bottom surface of the supply nozzle 33 and the conveying plane P9) is exaggerated. Actual thickness of the processing space 19 is about 0.5 to 5 mm.

An entrance port 13 is formed in an entrance side wall 11 on one end side (right side in FIG. 1) of the processing tank 10. An exit port 14 is formed in an exit side wall 12 on the other end side (left side in FIG. 1) of the processing tank 10. Each of the openings 13, 14 is defined by a pair of flow guide plates 15, 15. In each of the walls 11, 12, the pair of flow guide plates 15, 15 are disposed vertically opposed to each other. Each of the flow guide plates 15, 15 has a configuration of an elongated plate extending in the direction orthogonal to the plane of FIG. 1. A gap having a configuration of a slit extending in the direction orthogonal to the plane of FIG. 1 is formed between the upper and lower flow guide plates 15, 15. The slit-like gaps are the openings 13, 14. A width (dimension in the direction orthogonal to the plane of FIG. 1) of the openings 13, 14 is slightly greater than a dimension of the substrate 9 in the same direction. Preferably, a thickness (dimension in a vertical direction) of the openings 13, 14, i.e., a distance between opposing surfaces of the pair of flow guide plates 15, 15 is twice to ten times a thickness of the substrate 9. A height (location in the vertical direction) of the openings 13, 14 is adapted to coincide with a height (location in the vertical direction) of the conveying plane P9 of the substrate 9. The openings 13, 14 are constantly open and not adapted to be opened and closed. It is not necessary to provide doors in the walls 11, 12 for opening and closing the openings 13, 14.

As mentioned above, a width of the substrate 9 which is a glass substrate for a flat panel display is about 1100 mm, for example. On the other hand, the width of the openings 13, 14 of this embodiment is about 1200 mm. A thickness of the substrate 9 which is a glass substrate for a flat panel display is generally about 0.7 mm. On the other hand, the thickness of the openings 13, 14 in this embodiment is about 5 mm.

The entrance port 13 and the exit port 14 are disposed on opposite sides of the processing space 19, each spaced apart from the processing space 19. Preferably, a spaced distance D1 between the entrance port 13 and the processing space 19 is D1=150 to 300 mm. The distance D1 is equal to a spaced distance in a horizontal direction between an inner end portion (end portion inside the processing tank 10) of the flow guide plate 15 of the entrance port 13 and, of the nozzle discharge openings 34 and the local exhaust openings 45 of the supply nozzle 33, the one that is located nearest to the entrance port 13. Preferably, a spaced distance between the exit port 14 and the processing space 19 (a spaced distance in a horizontal direction between an inner end portion of the flow guide plate 15 of the exit port 14 and, of the nozzle discharge openings 34 and the local exhaust openings 45, the one that is located nearest to the exit port 14) is equal to the spaced distance D1 between the entrance port 13 and the processing space 19.

The gas line 2 has a supply system 30, an exhaust system 40 and a recycle system 50.

The supply system 30 has a raw material gas supply unit 31 and a supply nozzle 33. A supply passage 32 extends from the raw material gas supply unit 31. The supply passage 32 is connected to the supply nozzle 33. The supply nozzle 33 is disposed in a ceiling portion of the processing tank 10. Though not shown in the drawings in detail, the supply nozzle 33 extends in the direction orthogonal to the plane of FIG. 1. The nozzle discharge openings 34 and the local exhaust openings 45 are formed in the bottom surface of the supply nozzle 33 (nozzle distal end surface). The nozzle discharge openings 34 and the local exhaust openings 45 have a configuration of a slit extending in the direction orthogonal to the plane of FIG. 1. Lengths of the nozzle discharge openings 34 and the local exhaust openings 45 in the direction orthogonal to the plane of FIG. 1 are generally the same as or slightly greater than the dimension of the substrate 9 in the same direction.

The nozzle discharge openings 34 and the local exhaust openings 45 are arranged in the left-right direction (conveying direction of the substrate 9) spaced from each other. The local exhaust openings 45 are located to the immediate left and right of each of the nozzle discharge openings 34. On the outermost sides of the bottom surface of the supply nozzle 33 in the left-right direction, the local exhaust openings 45 are respectively disposed. As mentioned above, the local exhaust openings 45 disposed on the outermost sides define the end portions of the processing space 19. The number and locations of the nozzle discharge openings 34 and the local exhaust openings 45 are not limited to those depicted in the drawings. In the drawings, the nozzle discharge openings 34 and the local exhaust openings 45 are alternately arranged. However, more than two local exhaust openings 45 may be disposed between the adjoining nozzle discharge openings 34, or more than two nozzle discharge openings 34 may be disposed between the adjoining local exhaust openings 45. Alternatively, no local exhaust openings 45 may be disposed in the supply nozzle 33 and the exhaust of the processing tank 10 may be performed only through an exhaust opening 43 to be described later.

The supply system 30 supplies a processing gas including reactive components and their raw materials suitable for the kind of processing to take place in the processing space 19. It is not uncommon for processing gas components (such as the reactive components and the raw materials mentioned above) to have environmental impact or have toxicity or corrosiveness. In this embodiment related to the etching of silicon, fluorine reactive components and oxidizing reactive components are used. The fluorine reactive components may include HF, COF₂ and fluorine radicals. The fluorine reactive components can be generated, for example, by humidifying a fluorine raw material humidified with water (H₂O) and subsequently plazmatizing (including decomposition, excitation, activation and ionization) the humidified fluorine raw material. In this embodiment, CF₄ is used as the fluorine raw material. Instead of CF₄, other PFCs (perfluorocarbons) such as C₂F₆, C₃F₈ and C₃F₈, HFCs (hydrofluorocarbons) such as CHF₃, CH₂F₂ and CH₃F or fluorine-containing compounds other than PFSs or HFCs such as SF₆, NF₃ and XeF₂ may be used as the fluorine raw material.

The fluorine raw material may be diluted with a diluent gas. Rare gas such as Ar and He or N₂ may be used as the diluent gas, for example. Instead of water (H₂O), chemical compounds containing OH group such as alcohol may be used as an additive to the fluorine raw material.

The oxidizing reactive components may be O₃ or O radicals or the like. In this embodiment, O₃ is used as the oxidizing reactive component. O₃ can be generated from oxygen (O₂) as raw material by using an ozonizer. Alternatively, the oxidizing reactive components may be generated by plasmatizing an oxygen raw material such as O₂.

The plasmatization of the fluorine raw material or the oxygen raw material can be performed by introducing gas including the raw material mentioned above to a plasma space between a pair of electrodes of a plasma generating apparatus. Preferably, the plasmatization is performed under near atmospheric pressure. More preferably, pressure in the plasma space between the electrodes is near atmospheric pressure. Near atmospheric pressure refers to a pressure in the range of 1.013×10⁴ to 50.663×10⁴ Pa. Considering the ease of pressure regulation and the simplicity of the structure of the apparatus, a pressure in the range of 1.333×10⁴ to 10.664×10⁴ Pa is preferable and a pressure in the range of 9.331×10⁴ to 10.397×10⁴ Pa is more preferable.

In this embodiment, a fluorine raw material gas (CF₄+Ar+H₂O) is obtained by diluting CF₄ as the fluorine raw material with Ar at the raw material gas supply unit 31 and adding H₂O. The fluorine raw material gas is led to the supply nozzle 33 through the supply passage 32. A pair of electrodes (not shown) are disposed at the supply nozzle 33. The fluorine raw material gas is plasmatized between the electrodes. The supply nozzle 33 also serves as a plasma generating apparatus. The fluorine reactive components such as HF are generated in this way. Though not shown in the drawings, O₃ as an oxidizing reactive component is separately generated by the ozonizer and led into the supply nozzle 33 and mixed with the plasmatized gas. As a result, the processing gas containing the fluorine reactive components (HF, etc.) and the oxidizing reactive components (O₃, etc.) is generated. Needless to say, raw material gas components (CF₄, H₂O, Ar, O₂, etc.) are also contained in the processing gas. The processing gas is discharged into the processing space 19 through the nozzle discharge opening 34.

Alternatively, the processing gas containing the fluorine reactive components and the oxidizing reactive components may be generated at the gas supply unit 31 and the processing gas may be sent to the supply nozzle 33 via the supply passage 32 and discharged through the nozzle discharge opening 34.

The processing gas discharged through the nozzle discharge opening 34 may be discharged onto the substrate 9 in the processing space 19 to perform surface processing of the substrate 9. In silicon etching, the silicon is oxidized by oxidizing components (such as O₃) in the processing gas, then the oxidized silicon reacts with the fluorine reactive components (such as HF) in the processing gas to generate volatile SiF₄ products. As a result, the silicon layer on the surface of the substrate can be removed.

The processing tank exhaust system 40 is described hereinafter. The exhaust opening 43 is provided in a generally central portion, for example, of a bottom portion of the processing tank 10. An exhaust passage 42 extends from the exhaust opening 43. An exhaust pump 41 is connected to the exhaust passage 42. Though not shown in the drawings, a suction passage that continues to the local exhaust openings 45 communicates with an upper portion of the supply nozzle 33. The suction passage merges into the exhaust passage 42. The local exhaust openings 45 and the suction passage between the local exhaust openings 45 and the exhaust passage 42 are also components of the exhaust system 40.

Running of the exhaust pump 41 causes the gas inside the processing tank 10 to be suctioned to the exhaust opening 43 and to be sent to the exhaust pump 41 via the exhaust passage 42. In addition, the processing gas that has been blown onto the substrate 9 in the processing space 19 (to be referred to as “used processing gas” hereinafter) is suctioned mainly into the local exhaust openings 45 and merges into the exhaust passage 42 via the suction passage that is not shown. The used processing gas contains the constituents of the processing gas (HF, O₃, CF₄, H₂O and Ar, etc.) and by-products (SiF₄, etc.) of the surface processing reaction. There is a possibility that a portion of the used processing gas will leak from the processing space 19. Such used processing gas is suctioned through the exhaust opening 43.

An exhaust gas flow rate at the exhaust system 40 is greater than a processing gas supply flow rate at the supply system 30. For example, in this embodiment, while the processing gas supply flow rate is about 32 slm, the exhaust gas flow rate is about 200 to 400 slm. Therefore, ambient gas (air) g flows into the inside of the processing tank 10 via the openings 13, 14 from the outside of the processing tank 10 at a flow rate corresponding to a difference between the exhaust gas flow rate and the processing gas supply flow rate.

Here, an average flow velocity of an inflow gas g flowing into the processing tank 10 through the openings 13, 14 is set to be at least 0.1 m/sec, and preferably set to be at least 0.3 m/sec. An upper limit of the average flow velocity of the inflow gas g is set to be smaller than a velocity at which the inflow gas g reaches the processing space 19. In this embodiment, the average flow velocity of the inflow gas g is preferably not greater than 2 m/sec, more preferably not greater than 1 m/sec, and further more preferably not greater than 0.7 m/sec. The set average flow velocity mentioned above is preferably a velocity determined under a condition in which the substrate 9 is not located inside or near the openings 13, 14.

The average flow velocity of the inflow gas g can be regulated by dimensions of the processing tank 10 and the exhaust flow rate at the exhaust system 40, etc. Of the dimensions of the processing tank 10, the thickness (vertical dimension) of the openings 13, 14 greatly affects the average flow rate of the inflow gas g. Specifically, the thickness of the openings 13, 14 is preferably set in a range of 2 to 8 mm, and more preferably set at about 5 mm. The exhaust flow rate at the exhaust system 40 may be set in a range of 200 to 400 slm when the processing gas supply flow rate is about 32 slm as mentioned above.

In general, an average flow velocity of an inflow gas through openings for conveying into and out of a processing tank in an ordinary surface processing apparatus for flat panel displays is greater than 2 m/sec.

In order to make the upper limit of the average flow velocity of the inflow gas g smaller than a velocity at which the inflow gas g reaches the processing space 19, the average flow velocity of the inflow gas g may be regulated. Alternatively, the spaced distance D1 between the openings 13, 14 and the processing space 19 may be adjusted.

Most of the exhaust gas exhausted from the processing tank 10 by the exhaust system 40 is air entered from the outside through the entrance and exit ports 13, 14. Therefore, the gas constituent that accounts for the greatest percentage of the exhaust gas is nitrogen. The exhaust gas further contains the constituents of the used processing gas (HF, O₃, CF₄, H₂O, Ar, SiF₄, etc.). Although not shown in the drawings, a scrubber that removes HF, etc. from the exhaust gas, a mist trap that removes H₂O from the exhaust gas and an ozone killer that removes O₃ from the exhaust gas, etc. are disposed in the exhaust passage 42 between the exhaust opening 43 and the exhaust pump 41.

The recycle system 50 is connected to the exhaust system 40. The recycle system 50 collects the reactive constituents of the processing gas from the gas exhausted by the exhaust system 40. Specifically, the recycle system 50 includes a separation-recovery unit 51. A separation membrane 52 is provided in the separation-recovery unit 51. The separation membrane 52 partitions the inside of the separation-recovery unit 51 into a concentration chamber 53 and a dilution chamber 54. For the separation membrane 52, a glass polymer membrane (U.S. Pat. No. 3,151,151, etc.) is used, for example. A rate at which the separation membrane 52 allows CF₄ (reactive constituent) to permeate therethrough is relatively small and a rate at which the separation membrane 52 allows nitrogen (impure substance) to permeate therethrough is relatively great. A portion of the exhaust passage 42 further downstream than the exhaust pump 41 continues to the concentration chamber 53. The exhaust gas from the exhaust pump 41 is directed into the concentration chamber 53 and separated by the separation membrane 52 into a recovered gas that will remain in the concentration chamber 53 and a release gas that will enter the dilution chamber 54 through the separation membrane 52. A concentration of CF₄ in the recovered gas is high (CF₄₌₉₀ vol % or more) and a flow rate of the recovered gas is low. A concentration of CF₄ in the release gas is low (CF₄=1 vol % or less) and a flow rate of the release gas is high.

Although only one separation-recovery unit 51 is shown in the drawing, the recycle system may include a plurality of separation-recovery units 51. The plurality of separation-recovery units 51 may be connected in series, may be connected in parallel or may be connected in a combination of series and parallel.

A recovery passage 55 extends from a downstream end of the concentration chamber 53. The recovery passage 55 is connected to the raw material gas supply unit 31.

A release passage 46 extends from the dilution chamber 54. The release passage 46 is connected to a detoxifier 47.

According to the surface processing apparatus 1 having the above described construction, the substrate 9 is placed on the roller 21 and is conveyed along the conveying plane P9. The substrate 9 is conveyed to the inside of the processing tank 10 through the entrance port 13 and introduced to the processing space 19. The processing gas is supplied to the processing space 19 by the supply system 30. The processing gas is contacted with the substrate 9, thereby surface processing such as etching is performed. After the processing, substrate 9 is guided out of the processing space 19 and conveyed out of the processing tank 10 through the exit port 14. The plurality of substrates 9 are placed in a spaced arrangement on the roller conveyor 20 in a single-row, conveyed into the processing tank 10, and after being surface processed, conveyed out of the processing tank 10 in a continuous manner.

Concurrently with the supplying of the processing gas, the gas inside the processing tank 10 is suctioned through the exhaust opening 43 and the local exhaust openings 45 by the exhaust system 40. With this suctioning, the ambient gas (air) outside the processing tank 10 flows into the inside of the processing tank 10 via the entrance and exit ports 13, 14. By setting the average flow velocity of the inflow gas g to be at least 0.1 m/sec, preferably at least 0.3 m/sec, the used processing gas inside the processing tank 10 can be prevented from leaking to the outside through the openings 13, 14. Thus, the safety of the operation can be secured even when toxic constituents are contained in the processing gas or the used processing gas. Moreover, even when constituents such as CF₄, having high global warming potential are contained in the processing gas or the used processing gas, influence on the environment can be sufficiently reduced. Furthermore, corrosion of devices in the vicinity can be prevented.

By setting the upper limit of the average flow velocity of the inflow gas g, the inflow gas g can be sufficiently attenuated on the way to the processing space 19. Therefore, the inflow gas g cannot reach the processing space 19. This can prevent the flow of the processing gas in the processing space 19 from being disturbed by the inflow gas g, thereby stabilizing the flow of the processing gas. By setting the average flow velocity of the inflow gas g to be preferably not greater than 2 m/sec, more preferably not greater than 1 m/sec, and further more preferably not greater than 0.7 m/sec, the flow of the processing gas in the processing space 19 can be securely prevented from being disturbed by the inflow gas g, thereby further stabilizing the flow of the processing gas. This enables the surface processing to be performed in a stable manner.

Moreover, since the inside of the processing tank 10 can be constantly ventilated by the inflow gas g from the outside, the concentration of the processing gas inside the processing tank 10 can be kept constant, thereby further stabilizing the surface processing.

The gas exhausted from the processing tank 10 by the exhaust system 40 is led into the separation-recovery unit 51 and is separated into the recovered gas having the high CF₄ concentration and the release gas having the low CF₄ concentration. The recovered gas is sent to the raw material gas supply unit 31 through the recovery passage 55. This returns the reactive components (CF₄) collected at the separation-recovery unit 51 to the raw material gas supply unit 31 for recycling. Therefore, a total amount of CF₄ used by the surface processing apparatus 1 can be reduced, thereby restraining the running cost.

The release gas, after being sent to the detoxifier 47 and detoxified by the detoxifier 47, is released to the atmosphere.

Since the exhaust gas flow rate at the exhaust system 40 is relatively small, consequently the flow rate of the ambient gas taken into the processing tank 10 from the outside is relatively small, enabling the load on the separation-recovery unit 51 to be reduced. Furthermore, the load on the detoxifier 47 can also be reduced. This enables the separation-recovery unit 51 and the detoxifier 47 to be downsized.

Other embodiments of the present invention will now be described. In the drawings, the same reference numerals will be used to designate the same elements as aforementioned embodiments and the description thereof will be omitted.

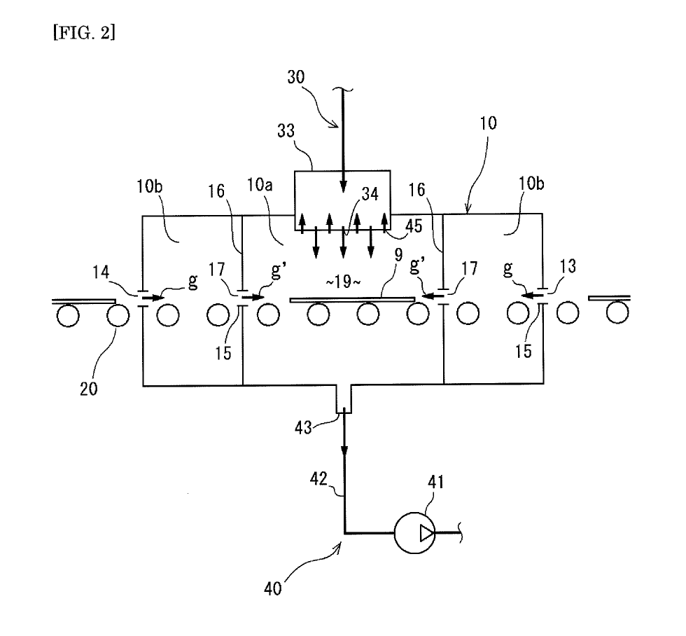

FIG. 2 shows a second embodiment of the present invention. In this embodiment, two (plurality of) partitioning walls 16 are provided in the processing tank 10. The inside of the processing tank 10 is partitioned by the partitioning walls 16 into three (plurality of) chambers 10b, 10a, 10b arranged in the left-right direction (conveying direction of the substrate 9). The processing space 19 is provided in the first chamber 10a in the middle (chamber other than those located at opposite ends). The supply system 30 and the exhaust system 40 are directly connected to the first chamber 10a. Specifically, the supply nozzle 33 is disposed in the upper portion of the first chamber 10a and the exhaust opening 43 is provided in the bottom portion of the first chamber 10a.

A communication opening 17 is provided in the partitioning wall 16. The communication opening 17 is defined by a pair of flow guide plates 15, 15 vertically opposed to each other in a similar manner to the openings 13, 14. A dimension of the partitioning wall 16 and a location of the partitioning wall 16 in the vertical direction are preferably the same as those of the openings 13, 14. The substrate 9 is conveyed into the chamber 10b at a right end through the entrance port 13 by the conveyor 20. Then, the substrate 9 is passed through the communication opening 17 in the right side, conveyed into the first chamber 10a, introduced to the processing space 19 and surface processed. The substrate 9 after the surface processing is passed through the communication opening 17 in the left side, conveyed into the chamber 10b at a left end, further passed through the exit port 14 and conveyed to the outside of the processing tank 10.

Actuation of the exhaust pump 41 causes the ambient gas outside to enter the chambers 10b at the opposite ends through the openings 13, 14. Gas inside the chambers 10b at the opposite ends containing the inflow gas g through the openings 13, 14 flows through the communication opening 17 into the first chamber 10a in the middle (downstream side). An average flow velocity of gas g′ at the time of flowing into the first chamber 10a is set to be at least 0.1 m/sec, and preferably set to be at least 0.3 m/sec determined under a condition in which the substrate 9 is not located inside or near the communication opening 17 as with the inflow gas g through the openings 13, 14.

An upper limit of the average flow velocity of the inflow gas g′ is set to be smaller than a velocity at which the inflow gas g′ reaches the processing space 19. Specifically, the average flow velocity of the inflow gas g′ is preferably set to be not greater than 2 m/sec, more preferably set to be not greater than 1 m/sec, and further more preferably set to be not greater than 0.7 m/sec. The average flow velocity of the inflow gas g′ can be regulated by the dimensions (especially a thickness (dimension in the vertical direction) of the communication opening 17) of the processing tank 10 or the flow rate at the exhaust system 40, etc. To make the upper limit of the average flow velocity of the inflow gas g′ smaller than the velocity at which the inflow gas g′ reaches the processing space 19, aside from regulating the average flow velocity of the inflow gas g′, a spaced distance between the communication opening 17 and the processing space 19 may be adjusted.

In the second embodiment, since the partitioning walls 16 are provided between the first chamber 10a and the openings 13, 14, the used processing gas in the first chamber 10a can be more securely prevented from leaking to the outside of the processing tank 10. Moreover, by setting a range for the average flow velocity of the inflow gas g′, the used processing gas can be more securely prevented from leaking. This can further ensure the safety of the operation, sufficiently reduce the environmental impact, and prevent the corrosion of the devices in the vicinity. Moreover, the flow of the processing gas in the processing space 19 can be protected from being disturbed by the inflow gas g′, the flow of the processing gas can be stabilized, and the stability of the surface processing can be secured.

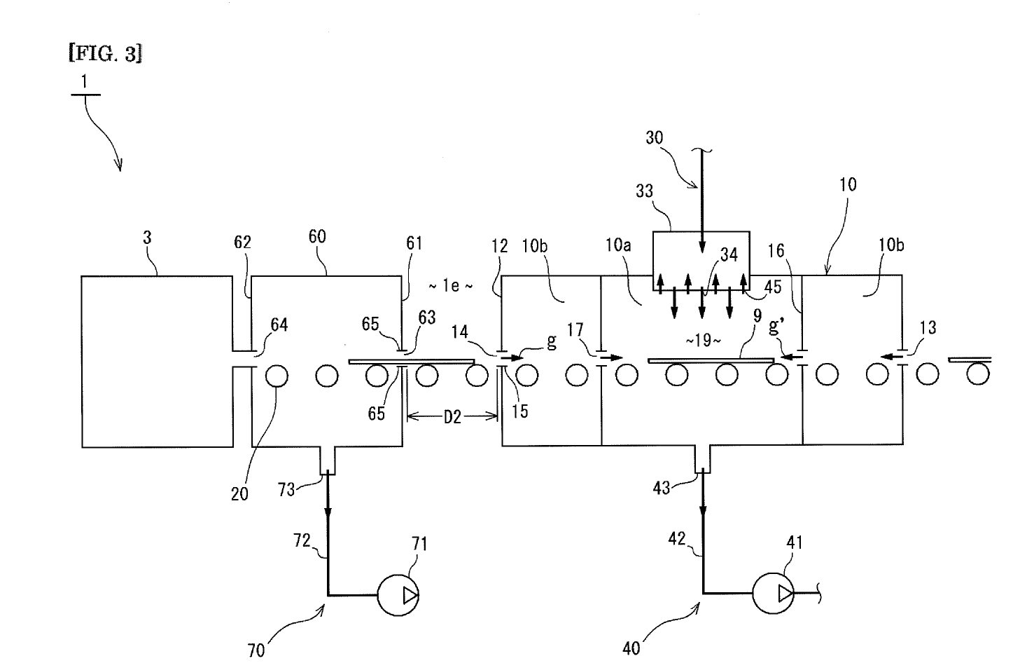

FIG. 3 shows a third embodiment of the present invention. In this embodiment, a cleaning unit 3 as a post-processor is disposed in the downstream side (left side in FIG. 3) of the processing tank 10 in the conveying direction. The cleaning unit 3 wet-cleans the substrate 9 that has been surface-processed in the processing space 19. The post-processing performed in the post-processor is not limited to wet-cleaning, but may also be dry-cleaning using the atmospheric pressure plasma, for example.

A post-processing waiting tank 60 is disposed between the processing tank 10 and the cleaning unit 3. An entrance port 63 is formed in a wall 61 of the post-processing waiting tank 60 on the processing tank 10 side. The entrance port 63 is defined by a pair of flow guide plates 65, 65 opposed to each other in the vertical direction in a similar manner to the flow guide plates 15 of the processing tank 10. Dimensions of the entrance port 63 and a location of the entrance port 63 in the vertical direction are preferably the same as those of the openings 13, 14, 17.

An exit port 64 is formed in a wall 62 of the waiting tank 60 on the cleaning unit 3 side. A width (dimension in a direction orthogonal to the plane of FIG. 3) and a thickness (dimension in the vertical direction) of the exit port 64 and a location of the exit port 64 in the vertical direction are preferably the same as those of the openings 13, 14, 17, 63. The exit port 64 communicates with the cleaning unit 3. The conveyor 20 comprised of a roller conveyor is disposed so as to extend to an inside of the waiting tank 60.

The exit side wall 12 of the processing tank 10 and the entrance side wall 61 of the waiting tank 60 are spaced apart from each other, and a gap 1e is formed between the walls 12, 61. A spaced distance D2 between the exit port 14 in the exit side wall 12 and the entrance opening 63 in the entrance side wall 61 (to be precise, the distance between the flow guide plates 15 of the exit port 14 and the flow guide plates 65 of the entrance port 63) is set to be in a range of D2=20 to 300 mm.

A second exhaust system 70 (waiting tank exhaust system) is connected to the post-processing waiting tank 60. An exhaust opening 73 of the second exhaust system 70 is provided in a bottom portion of the waiting tank 60. An exhaust passage 72 extends from the exhaust opening 73. An exhaust pump 71 is connected to the exhaust passage 72. The detoxifier 47 may be connected downstream of the exhaust passage 71. Furthermore, the exhaust passage 72 may be merged into the exhaust passage 42 and the exhaust pump 71 may be omitted, for example. In other words, the processing tank exhaust system 40 and the waiting tank exhaust system 60 may share a common exhaust pump 41 and the processing tank exhaust pump 41 may also serve as the waiting tank exhaust pump.

Since the distance D2 between the exit port 14 and the entrance port 63 is set to be a distance that is not too small (D2≧20 mm) in the third embodiment, the gap 1e can be put under the same pressure environment as the outside (atmospheric pressure), thereby preventing a pressure inside the processing tank 10 and a pressure inside the post-processing waiting tank 60 from affecting each other. This can prevent the gas inside the processing tank 10 from leaking through the exit port 14 and being suctioned into the waiting tank 60 even when the pressure inside the waiting tank 60 is reduced by the second exhaust system 70, for example. Furthermore, an exhaust flow rate from each of the two tanks 10, 60 can be easily regulated.

The substrate 9 brought out of the processing tank 10 through the exit port 14 by the conveyor 20 is passed through the gap 1e. There may be cases in which the constituents of the processing gas or the constituents of the used processing gas are attached or adsorbed to the substrate 9 that has gone through the surface processing. However, the time during which the substrate 9 is passed through the gap 1e can be made sufficiently short because the distance D2 between the exit port 14 and the entrance port 63 is set at a distance that is not too great (D2≦300 mm). Therefore, an amount of the attached or adsorbed constituents that volatize from the substrate 9 being passed through the gap 1e can be sufficiently minimized. The substrate 9 that has been passed through the gap 1e is passed through the entrance port 63 and conveyed into the inside of the waiting tank 60, where the substrate 9 is in a state of waiting for the post-processing. However, the substrate 9 is continuously conveyed toward the post processor 3 even during the time when the substrate 9 is waiting for the post-processing. If the attached or adsorbed constituents volatilize from the substrate 9 during the state of waiting, the volatilized gas can be confined inside the post-processing waiting tank 60 and can be prevented from leaking to the outside. Moreover, the volatilized gas constituents can be exhausted to the exhaust passage 72 from the post processing waiting tank 60 by the second exhaust system 70. By this arrangement, the safety of the operation can be further secured, the environmental impact can be sufficiently reduced and the corrosion of the devices in the vicinity can be securely prevented.

Subsequently, the substrate 9 is conveyed through the exit port 64, guided to the cleaning unit 3 and clean-processed.

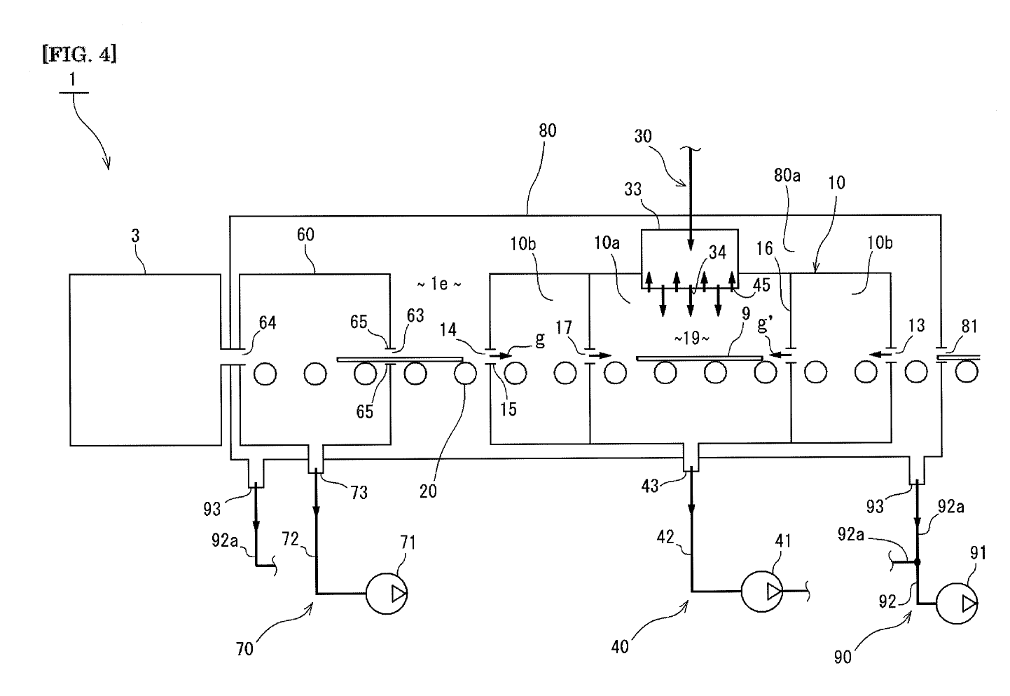

FIG. 4 shows a fourth embodiment of the present invention. The surface processing apparatus 1 of this embodiment further includes an outer tank 80 and a pressure reducer 90. The outer tank 80 encloses the processing tank 10 and the post-processing waiting tank 60. An entrance port 81 is provided in a wall of the outer tank 80 at a right end (end portion on the upstream side in the conveying direction of the substrate 9). Dimensions of the entrance port 81 and a location of the entrance port 81 in the vertical direction are preferably the same as those of the openings 13, 14, 17.

The pressure reducer 90 is connected to the outer tank 80. The pressure reducer 90 is constructed as follows. A plurality (two in the drawings) of suction openings 93 of the pressure reducer 90 are provided in a bottom portion of the outer tank 80 spaced apart from each other. An individual suction passage 92a extends from each of the suction openings 93. The individual suction passages 92a from the suction openings 93 merge with each other into a suction passage 92, and the suction passage 92 is connected to a pressure reducing pump 91. The pump 91 and the pump 41 or 71 may be constituted by one common suction pump, and only one suction opening 93 may be provided in the outer tank 80, for example.

Activation of the pressure reducing pump 91 reduces a pressure of a space 80a between the outer tank 80 and the inner tanks 10, 60 to be slightly lower than the atmospheric pressure. Specifically, it is preferable that an inner pressure of the inter-tank space 80a is lower than the atmospheric pressure by about 10 Pa.

According to the fourth embodiment, even if the used processing gas leaks from the processing tank 10, or volatilized gas is generated from the substrate 9 while the substrate 9 is passed through the gap 1e, or gas volatilized in the post-processing waiting tank 60 leaks from the post-processing waiting tank 60, the used processing gas or the volatilized gas can be confined in the inter-tank space 80a. This can more securely prevent the used processing gas or the volatilized gas from leaking into the ambient air in the outside. Moreover, since the pressure in the inter-tank space 80a is slightly lower than the atmospheric pressure, the gas inside the inter-tank space 80a can be further securely prevented from leaking out of the outer tank 80. By this arrangement, the safety of the operation can be further secured, the environmental impact can be further minimized and the corrosion of devices in the vicinity can be securely prevented. The processing gas and the used processing gas leaked into the inter-tank space 80a can be exhausted from the inter-tank space 80a via the suction passage 92.

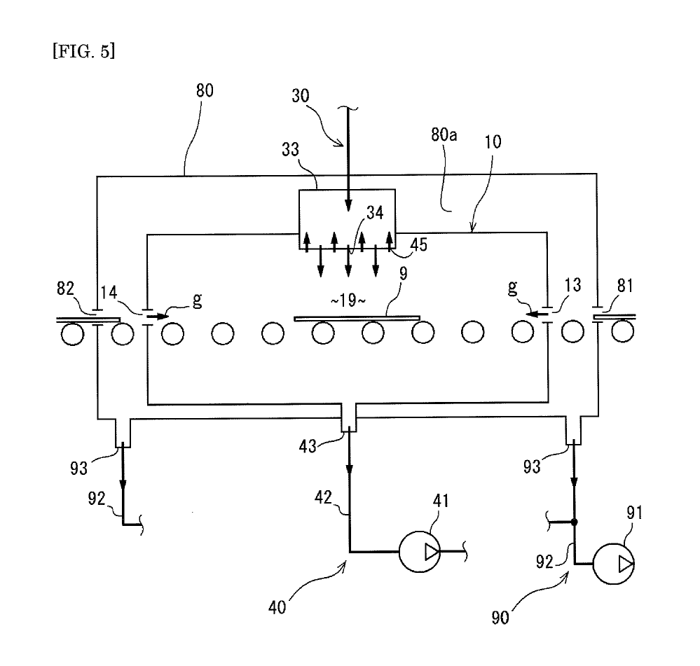

FIG. 5 shows the fifth embodiment of the present invention. In this embodiment, the outer tank 80 and the pressure reducer 90 are applied to the first embodiment (FIG. 1). The outer tank 80 encloses the processing tank 10. An exit port 82 is provided in a wall of the outer tank 80 at a left end (end portion on the downstream side in the conveying direction of the substrate 9). Dimensions of the entrance port 82 and a location of the entrance port 82 in the vertical direction are preferably the same as those of the openings 13, 14, 81.

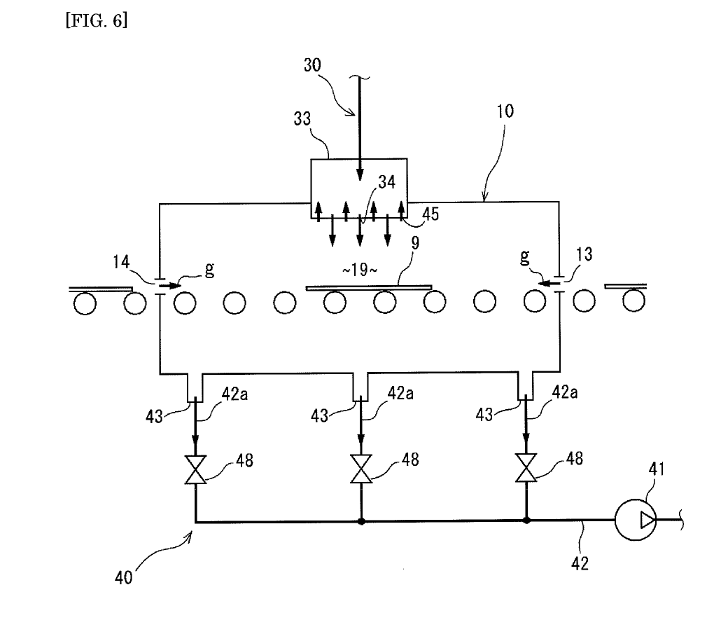

FIG. 6 shows the sixth embodiment of the present invention. In this embodiment, a plurality (three in the drawing) of the exhaust openings 43 of the exhaust system 40 are provided. The plurality of exhaust openings 43 are arranged in the bottom portion of the processing tank 10 in a dispersed manner. In FIG. 6, the plurality of exhaust openings 43 are arranged in a spaced configuration along the conveying direction of the substrate 9. The exhaust openings 43 are also arranged in a spaced configuration in a direction orthogonal to the conveying direction (direction orthogonal to the plane of FIG. 6). An individual exhaust passage 42a extends from each of the exhaust openings 43. The individual exhaust passages 42a merge with each other into the exhaust passage 42, and the exhaust passage 42 is connected to the exhaust pump 41. Though not shown in the drawing, the scrubber, the mist trap and the ozone killer are disposed in the merged exhaust passage 42.

A flow rate control valve 48 (regulator) is disposed in each of the individual exhaust passages 42a. The flow rate control valves 48 are provided for the exhaust openings 43 on a one-to-one basis and regulate the exhaust flow rate through each of the corresponding exhaust openings 43.

According to the sixth embodiment, each of the flow rate control valves 48 corresponding to the exhaust openings 43 can be individually operated, and the exhaust flow rate through each of the exhaust openings 43 can be regulated independently of the other exhaust openings 43. This enables the flow of the gas to be controlled over an entirety or a wide area of the inside of the processing tank 10. This enables the flow of the processing gas supplied to the processing space 19 from the supply system 30 to be controlled, thus preventing the flow of the processing gas from being unevenly distributed in one direction. Thus, homogeneity of the processing can be secured.

The present invention is not limited to the embodiments described above, but various modifications can be made without departing from the spirit and scope of the invention.

For example, the entrance port 13 and the exit port 14 may be composed of one common opening. The conveyor 20 may convey the substrate 9 into the inside of the processing tank 10 through the common opening and position the substrate 9 in the processing space 19 and after the surface processing, may convey the substrate 9 to the outside through the common opening. Furthermore, the conveying of the substrate 9 into the processing tank 10 and the conveying of the substrate 9 out of the processing tank 10 may be performed, aside from by means of the conveyor 20, by an operator, for example.

Location, bore diameter and number of the exhaust openings 43 may be determined so as to stabilize the flow of the processing gas in the processing space 19.

A plurality of embodiments may be combined. For example, the outer tank 80 and the pressure reducer 90 of the fourth and fifth embodiments (FIGS. 4 and 5) may be applied to the second embodiment (FIG. 2). With regard to the sixth embodiment (FIG. 6), if the plurality of exhaust openings 43 and the flow rate control valves 48 are applied to the processing tank 10 of the first embodiment (FIG. 1), the plurality of exhaust openings 43 and 48 of the sixth embodiment may be applied to the processing tank 10 of the second to the fifth embodiments (FIGS. 2 to 6).

Of the processing tank 10 and the post-processing waiting tank 60 of the fourth embodiment (FIG. 4), only the processing tank may be enclosed by the outer tank 80 and the post-processing waiting tank 60 may be disposed outside the outer tank 80, for example.

### INDUSTRIAL APPLICABILITY

The present invention may be applied to manufacturing of flat panel displays (FPDs) and semiconductor wafers.

### REFERENCE SIGNS LIST

1 surface processing apparatus
1e gap
3 cleaning unit (post-processing unit)
9 substrate
10 processing tank
10a first chamber
10b chamber
13 entrance port
14 exit port
16 partitioning wall
17 communication opening
19 processing space
20 conveyor
30 supply system
33 supply nozzle
34 nozzle discharge opening
40 exhaust system
42 exhaust passage
42a individual exhaust passage
43 exhaust opening
45 local exhaust opening
47 detoxifier
48 flow rate control valve (regulator)
50 recycle system
51 separation-recovery unit
55 recovery passage
60 post-processing waiting tank
63 entrance port
70 second exhaust system (waiting tank exhaust system)
80 outer tank
80a inter-tank space
81 entrance port
90 pressure reducer
g inflow gas flow
g′ inflow gas flow

1. A surface processing apparatus that processes a surface of a substrate by bringing a processing gas into contact with the surface of the substrate, the apparatus comprising:
a processing tank having an entrance port and an exit port, and a processing space disposed inside of the processing tank at a location spaced apart from the entrance port and the exit port for performing the surface processing;
a conveyor that conveys the substrate into the inside of the processing tank through the entrance port, positions the substrate in the processing space and subsequently conveys the substrate through the exit port;
a supply system that supplies the processing gas to the processing space; and
an exhaust system that exhausts gas from the inside of the processing tank,
wherein the exhausting of gas by the exhaust system causes a gas outside the processing tank to inflow into the inside of the processing tank through the port such that an average flow velocity of the inflow gas is at least 0.1 msec yet smaller than a velocity that would allow the inflow gas to reach the processing space.

2. The surface processing apparatus according to claim 1 wherein the average flow velocity is at least 0.3 msec.

3. The surface processing apparatus according to claim 1 wherein the average flow velocity is not greater than 2 msec.

4. The surface processing apparatus according to claim 1 wherein the average flow velocity is not greater than 1 msec.

5. The surface processing apparatus according to claim 1 wherein the average flow velocity is 0.3 m/sec to 0.7 m/sec.

6. The surface processing apparatus according to claim 1, wherein, the inside of the processing tank further includes one or more partitioning walls partitioning the inside of the processing tank into a plurality of chambers in a conveying direction of the conveying means, the one or more partitioning walls having a communication opening for passing the substrate therethrough, wherein the processing space is disposed inside of one of the plurality of chambers (referred to as a “first chamber” hereinafter) and the supply system and the exhaust system are directly connected to the first chamber, and wherein the exhausting of gas by the exhaust system causes the inflow gas to flow through the communication opening toward the processing space such that an average flow velocity at which the inflow gas that has passed through the communication opening flows into the chamber on a downstream side of the communication opening is at least 0.1 m/sec.

7. The surface processing apparatus according to claim 6 wherein the average flow velocity of the inflow gas on the downstream side is at least 0.3 m/sec.

8. The surface processing apparatus according to claim 6 wherein the processing space inside the first chamber is disposed spaced apart from the communication opening (referred to as “first communication opening” hereinafter) of the partitioning wall facing the first chamber and wherein the exhausting of the gas by the exhaust system causes the inflow gas to flow through the first communication opening toward the processing space such that an average flow velocity at which the inflow gas that has passed through the first communication opening flows into the first chamber is at least 0.1 m/sec yet smaller than a velocity that would allow the inflow gas to reach the processing space.

9. The surface processing apparatus according to claim 8 wherein the average flow velocity of the inflow gas is at least 0.3 m/sec.

10. The surface processing apparatus according to claim 1 wherein the exhaust system further includes a plurality of exhaust openings arranged in the processing tank in a dispersed manner and regulators that are provided for the exhaust openings on a one-to-one basis to regulate an exhaust flow rate through each of the corresponding exhaust openings.

11. The surface processing apparatus according to claim 1 further comprising a recycle system that collects reactive constituents of the processing gas from the gas exhausted by the exhaust system and sends the reactive constituents to the supply system.

12. The surface processing apparatus according to claim 1 further comprising:
a post-processor that is disposed downstream with respect to the processing tank in a conveying direction of the conveyor and performs a post-processing step;
a post-processing waiting tank disposed between the processing tank and the post-processor; and
a second exhaust system that exhausts gas from an inside of the post-processing waiting tank wherein the conveyor conveys the substrate conveyed out of the processing tank through the exit port to the post processor via the post-processing waiting tank.

13. The surface processing apparatus according to claim 12 wherein a second entrance port is provided in a wall of the post-processing waiting tank on the processing tank side; wherein a second exit port is provided in a wall of the post-processing waiting tank on the post-processor side; and the exit port of the processing tank and the second entrance port of the post-processing waiting tank are spaced apart from each other in the conveying direction by 20 to 300 mm.

14. The surface processing apparatus according to claim 1 further comprising:
an outer tank enclosing the processing tank; and
a pressure reducer that reduces a pressure of a space between the outer tank and the processing tank to below an atmospheric pressure.

15. The surface processing apparatus according to claim 12 further comprising:
an outer tank enclosing the processing tank and the post-processing waiting tank; and a pressure reducer that reduces a pressure of a space between the outer tank and the processing tank and between the outer tank and the post-processing waiting tank to below an atmospheric pressure.

16. A surface processing apparatus that processes a surface of a substrate by bringing a processing gas into contact with the surface of the substrate under a near atmospheric pressure, the apparatus comprising:
a processing tank having an entrance port and an exit port, and having a processing space disposed inside of the processing tank for performing the surface processing, the processing space being spaced apart from the entrance port in a downstream direction and also being spaced apart from the exit port in an upstream direction;
a conveyor that conveys the substrate in the downstream direction through the entrance port into the inside of the processing tank, positions the substrate in the processing space and subsequently conveys the substrate in the downstream direction out through the exit port;
a supply system that supplies the processing gas to the processing space;
an exhaust system that exhausts gas from the inside of the processing tank;
an outer tank enclosing the processing tank such that an inter-tank space is formed between the processing tank and the outer tank, the outer tank having ports that allow the substrate to be conveyed in and out therethrough, a first port being provided in a wall of the outer tank on an upstream side of the processing tank and a second port being provided in a wall of the outer tank on a downstream side of the processing tank; and
a pressure reducer that reduces a pressure of the inter-tank space to near and below an atmospheric pressure wherein the pressure reducer suctions a gas from the inter-tank space through a suction opening located in a portion of the inter-tank space on the upstream side of the processing tank or a portion of the inter-tank space on the downstream side of the processing tank, and wherein the exhausting of gas by the exhaust system causes the gas in the inter-tank space to inflow into the inside of the processing tank through the entrance port and the exit port such that an average flow velocity of the inflow gas is at least 0.1 msec and an inner pressure of the processing tank is near atmospheric pressure and lower than the pressure of the inter-tank space such that the inflow gas from the inter-tank space cannot reach the processing space.

17. A surface processing method for processing a surface of a substrate by bringing a processing gas into contact with the surface of the substrate under a near atmospheric pressure,
the method using a surface processing apparatus comprising:
a processing tank having a first entrance port and a first exit port, and having a processing space disposed inside of the processing tank for performing the surface processing, the processing space being spaced apart from the first entrance port in a downstream direction and also being spaced apart from the first exit port in an upstream direction; a conveyor for conveying the substrate; a supply system for supplying the processing gas; an exhaust system connected to the processing tank; an outer tank enclosing the processing tank such that an inter-tank space is formed between the processing tank and the outer tank, a second entrance port provided in a wall of the outer tank on an upstream side of the processing tank, a second exit port provided in a wall of the outer tank on a downstream side of the processing tank; and a pressure reducer that includes a suction opening located in a portion of the inter-tank space on an upstream side of the processing tank or a portion of the inter-tank space on a downstream side of the processing tank;
the method comprising steps of:
conveying the substrate by the conveyor in the downstream direction through the second entrance port and the first entrance port into the inside of the processing tank and positioning the substrate in the processing space;
supplying the processing gas from the supply system to the processing space;
subsequently conveying the substrate by the conveyer in the downstream direction out through the first exit port and further conveying the substrate out through the second exit port; and
during the supplying of the processing gas, reducing an inner pressure of the inter-tank space to lower than the atmospheric pressure and higher than 1.013×10⁴ Pa and reducing an inner pressure of the processing tank to lower than the inner pressure of the inter-tank space and not lower than 1.013×10⁴ Pa by exhausting a gas inside the processing tank by means of the exhaust system and by suctioning a gas in the inter-tank space through the suction opening by means of the pressure reducer, thereby causing a gas in the inter-tank space to flow into the inside of the processing tank through the first entrance port and the first exit port at an average flow velocity of at least 0.1 msec yet a flow velocity smaller than a velocity that would allow the gas to reach the processing space.
